(19) United States
(12) Patent Application Publication
(10) Pub. No.: US 2025/0067524 A1
(43) Pub. Date: Feb. 27, 2025

(54) EVAPORATION APPARATUS INCLUDING ANGLE LIMITING PLATE

(71) Applicant: Samsung Display Co., LTD., Yongin-si (KR)

(72) Inventors: Hwa Pyeong JEONG, Yongin-si (KR); Eu Gene KANG, Yongin-si (KR); Kyoung Woon LEE, Yongin-si (KR); Seok Jun HONG, Yongin-si (KR); Jong Gun YUN, Yongin-si (KR)

(73) Assignee: Samsung Display Co., LTD., Yongin-si (KR)

(21) Appl. No.: 18/750,198

(22) Filed: Jun. 21, 2024

(30) Foreign Application Priority Data
Aug. 25, 2023 (KR) 10-2023-0112263

(51) Int. Cl. F28F 1/32; F28D 21/00; F28F 3/02

(52) U.S. Cl. CPC F28F 1/32; F28F 3/025; F28D 2021/0071

(57) ABSTRACT

An evaporation apparatus includes a lower case that accommodates a deposition material, a nozzle emitting the deposition material, a first angle limiting member including a first angle limiting plate extending in a direction that limits an angle of the deposition material emitted from the nozzle, a plurality of first cooling fins connected to a side of the first angle limiting member, and a first heat exchanger having a plurality of first heat exchange fins located between the plurality of first cooling fins.

### CROSS-REFERENCE TO RELATED APPLICATION(S)

This application claims priority to and benefits of Korean patent application No. 10-2023-0112263 under 35 U.S.C. § 119 (a), filed on Aug. 25, 2023, in the Korean Intellectual Property Office (KIPO), the entire contents of which are incorporated herein by reference.

### BACKGROUND

### 1. Technical Field

The disclosure relates to an evaporation apparatus including an angle limiting plate.

### 2. Description of the Related Art

With the development of information technologies, the importance of a display device which is a connection medium between a user and information increases. Accordingly, display devices such as a liquid crystal display device, an organic light emitting display device, and an inorganic light emitting display device are increasingly used.

In a process of manufacturing a display device, a layer may be formed using a method of depositing a deposition on a target substrate, using an evaporation apparatus. When several materials are to be sequentially deposited using several evaporation apparatuses, a section in which the deposited materials are mixed may exist.

In order to reduce or prevent this, a structure called an angle limiting plate may be used. The angle limiting plate may be installed above a nozzle through which a deposition material is emitted, thereby limiting an emission path of the deposition material to a desired range.

In the process, a portion of the deposition material, which is not deposited on the target substrate, may be piled up in a solid state in the vicinity of the angle limiting plate and the nozzle. When the deposition material is continuously piled up in the vicinity of the angle limiting plate and the nozzle, an emission angle limit of the deposition material, which designed at the beginning, may be changed, or a layer may not be formed with a desired layer thickness as the deposition material covers the nozzle.

The above information disclosed in this Related Art section is only for enhancement of understanding of the background of the disclosure and therefore it may contain information that does not form the prior art that is already known in this country to a person of ordinary skill in the art.

### SUMMARY

Embodiments provide an evaporation apparatus in which the emission angle limit of a deposition material is not changed. For example, the head dissipation effect of angle limiting members is increased, so that a material which is not deposited on a target substrate can be prevented from being piled up on surfaces of the angle limiting members. Accordingly, there can be provided an evaporation apparatus in which the emission angle limit of a deposition material is not changed.

In accordance with an embodiment of the disclosure, an evaporation apparatus may include a lower case that accommodates a deposition material, a nozzle mounted on the lower case, and emitting the deposition material, a first angle limiting member including a first support member and a first angle limiting plate connected to the first support member and extending, from the first support member, in a direction that limits an angle of the deposition material emitted from the nozzle, a second angle limiting member including a second support member and a second angle limiting plate connected to the second support member and extending, from the second support member, in a direction that limits the angle of the deposition material emitted from the nozzle, a plurality of first cooling fins connected to a side surface of the first angle limiting member, and a first heat exchanger having a plurality of first heat exchange fins, each of the plurality of the first heat exchange fins located between adjacent ones of the plurality of first cooling fins.

The first angle limiting member may overlap the lower case in a direction. The plurality of first cooling fins may extend from the first angle limiting member not to overlap the lower case in the direction.

The plurality of first heat exchange fins may overlap the plurality of first cooling fins in the direction without being in direct contact with the plurality of first cooling fins.

The plurality of first cooling fins and the plurality of first heat exchange fins may be alternately arranged in the direction.

Each of the first angle limiting plate and the second angle limiting plate may extend in a first direction and a second direction intersecting the first direction. Each of the first support member and the second support member may be fixed to the lower case, extend in a third direction intersecting the first and second directions, and support corresponding one of the first angle limiting plate and the second angle limiting plate. The first angle limiting member and the second angle limiting member may be spaced apart from each other in the first direction.

A length of one of the plurality of first cooling fins and a length of another one of the plurality of first colling fins may be different in the first direction.

The first angle limiting member and the second angle limiting member may include at least one of stainless steel, titanium, aluminum, and complex carbon.

The first heat exchanger may include a refrigerant material inlet for inputting a refrigerant material, a refrigerant material moving path connected to the refrigerant material inlet, the refrigerant material moving path being located inside the first heat exchanger, the refrigerant material moving path transferring the refrigerant material, and a refrigerant material outlet connected to an outside of the first heat exchanger, the refrigerant material outlet discharging, to outside, the refrigerant material transferred through the refrigerant material moving path.

The evaporation apparatus may further include a plurality of second cooling fins connected to a side surface of the second angle limiting member, and a second heat exchanger having a plurality of second heat exchange fins, each of the plurality of second heat exchange fins located between adjacent ones of the plurality of second cooling fins.

The second angle limiting member may overlap the lower case in a direction. The plurality of second cooling fins may extend from the second angle limiting member not to overlap the lower case in the direction.

The plurality of second heat exchange fins may overlap the plurality of second cooling fins in the direction without being in direct contact with the plurality of second cooling fins.

In accordance with another aspect of the disclosure, an evaporation apparatus may include a lower case that accommodates a deposition material, a nozzle mounted on the lower case, and emitting the deposition material, a first angle limiting member including a first support member and a first angle limiting plate connected to the first support member and extending, from the first support member, in a direction that limits an angle of the deposition material emitted from the nozzle, a second angle limiting member including a second support member and a second angle limiting plate connected to the second support member and extending, from the second support member, in a direction that limits the angle of the deposition material emitted from the nozzle, a plurality of first cooling fins connected to a side surface of the first angle limiting member, and a first heat exchanger in contact with at least one of the plurality of first cooling fins.

The evaporation apparatus may further include a plurality of second cooling fins connected to a side surface of the second angle limiting member, and a second heat exchanger in contact with at least one of the plurality of second cooling fins.

### BRIEF DESCRIPTION OF THE DRAWINGS

Embodiments will now be described more fully hereinafter with reference to the accompanying drawings; however, they may be embodied in different forms and should not be construed as limited to the embodiments set forth herein. Rather, these embodiments are provided so that this disclosure will be more thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a perspective view illustrating an evaporation apparatus in accordance with an embodiment of the disclosure.

FIG. 2 is a schematic cross-sectional view taken along line I-I′ of the evaporation apparatus shown in FIG. 1.

FIG. 3 is a schematic cross-sectional view taken along line II-II′ of a first heat exchange shown in FIG. 1.

FIG. 4 is a perspective view illustrating a second angle limiting member shown in FIG. 1.

FIG. 5 is a graph illustrating radiative heat radiated according to a number of second cooling fins of the second angle limiting member shown in FIG. 4.

FIG. 6 is a perspective view illustrating an evaporation apparatus in accordance with another embodiment of the disclosure.

### DETAILED DESCRIPTION OF THE EMBODIMENTS

Hereinafter, embodiments of the disclosure will be described in more detail with reference to the accompanying drawings. In the description below, only a necessary part to understand an operation according to the disclosure is described and the descriptions of other parts are omitted in order not to unnecessarily obscure subject matters of the disclosure. The disclosure is not limited to embodiments described herein, but may be embodied in various different forms. Rather, embodiments described herein are provided to thoroughly and completely describe the disclosed contents and to sufficiently transfer the ideas of the disclosure to a person of ordinary skill in the art.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element. The technical terms used herein are used only for the purpose of illustrating a specific embodiment and not intended to limit the embodiment.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It will be understood that for the purposes of this disclosure, “at least one of X, Y, and Z” can be construed as X only, Y only, Z only, or any combination of two or more items X, Y, and Z (e.g., XYZ, XYY, YZ, ZZ). Similarly, for the purposes of this disclosure, “at least one selected from the group consisting of X, Y, and Z” can be construed as X only, Y only, Z only, or any combination of two or more items X, Y, and Z (e.g., XYZ, XYY, YZ, ZZ).

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the disclosure.

Spatially relative terms, such as “below,” “above,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the exemplary term, “above,” may encompass both an orientation of above and below. The apparatus may be otherwise oriented (e.g., rotated 90 degrees or at other orientations) and the spatially relative descriptors used herein interpreted accordingly.

In addition, the embodiments of the disclosure are described here with reference to schematic diagrams of embodiments (and an intermediate structure) of the disclosure, so that changes in a shape as shown due to, for example, manufacturing technology and/or a tolerance may be expected. Therefore, the embodiments of the disclosure shall not be limited to the specific shapes of a region shown here, but include shape deviations caused by, for example, the manufacturing technology. The regions shown in the drawings are schematic in nature, and the shapes thereof do not represent the actual shapes of the regions of the device, and do not limit the scope of the disclosure.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

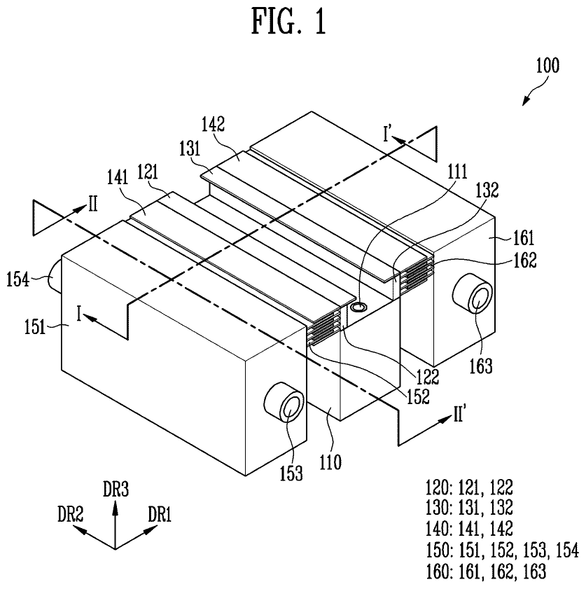

FIG. 1 is a perspective view illustrating an evaporation apparatus in accordance with an embodiment of the disclosure.

Referring to FIG. 1, the evaporation apparatus 100 may include a lower case 110, a first angle limiting member 120, a second angle limiting member 130, cooling fins 140, a first heat exchanger 150, and a second heat exchanger 160.

The lower case 110 may have a three-dimensional shape extending in a first direction DR1, a second direction DR2 intersecting the first direction DR1, and a third direction DR3 intersecting the first direction DR1 and the second direction DR2. For example, the lower case 110 may have a shape such as a hexahedron (e.g., a rectangular parallelepiped or a regular hexahedron).

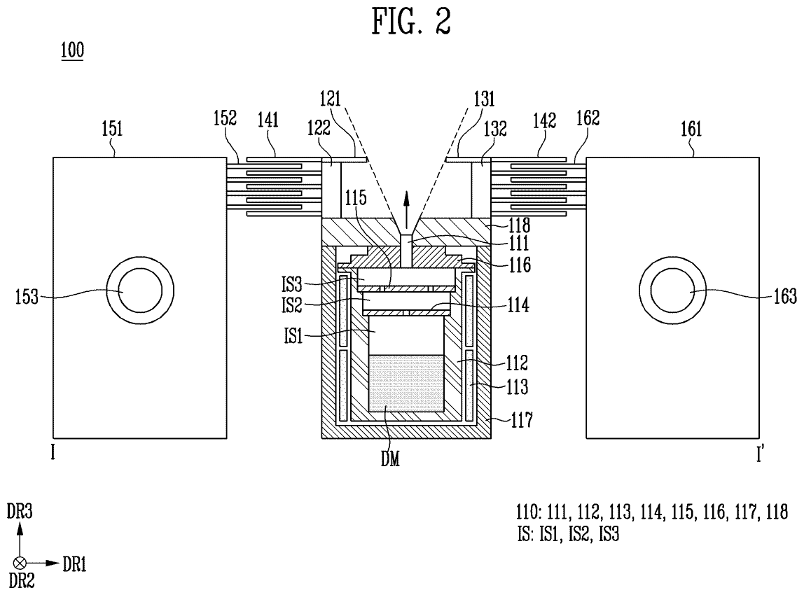

The lower case 110 may be configured to evaporate a deposition material DM (see FIG. 2) accommodated inside the lower case 110 to be emitted through a nozzle 111. The deposition material emitted through the nozzle 111 may form a thin film on a substrate overlapping the evaporation apparatus 100. An internal structure of the lower case 110 will be described in detail below with reference to FIG. 2.

The first angle limiting member 120 and the second angle limiting member 130 may be disposed on a heat insulating plate (not shown) while facing each other in the first direction DR1. Also, the first angle limiting member 120 and the second angle limiting member 130 may be coupled to the lower case 110. The first and second angle limiting members 120 and 130 may overlap the lower case 110 in a plan view.

The first angle limiting member 120 may include at least one of stainless steel, titanium, aluminum, and complex carbon. The second angle limiting member 130 may include at least one of stainless steel, titanium, aluminum, and complex carbon.

The first angle limiting member 120 and the second angle limiting member 130 may limit an emission area of the deposition material emitted in a radial form from the evaporation apparatus 100. In case that the evaporation apparatus 100 emits the deposition material in the radial form toward the substrate, the deposition material DM may not be deposited in an area blocked by the first angle limiting member 120 and the second angle limiting member 130. Therefore, the emission area of the deposition material emitted in the radial form from the evaporation apparatus 100 may be controlled.

The first angle limiting member 120 may include a first angle limiting plate 121 and a first support member 122.

The first angle limiting plate 121 may have a three-dimensional shape configured to have sides respectively extending in the first direction DR1, the second direction DR2, and the third direction DR3. For example, the first angle limiting plate 121 may have a rectangular parallelepiped plate shape. The first angle limiting plate 121 may be coupled to the first support member 122.

The first angle limiting plate 121 may extend in a direction (e.g., a nozzle direction) in which an angle at which the deposition material is emitted from nozzles 111 can be limited. The first angle limiting plate 121 may limit the emission area of the deposition material emitted in the radial form from the evaporation apparatus 100.

The first support member 122 may have a three-dimensional shape configured to have sides respectively extending in the first direction DR1, the second direction DR2, and the third direction DR3. For example, the first support member 122 may have a rectangular parallelepiped pillar shape.

The first support member 122 may function to entirely support the first angle limiting plate 121. For example, the shape of the first angle limiting plate 121 may be partially deformed by heat radiated from the lower case 110. The first support member 122 may function to entirely support the first angle limiting plate 121, thereby reducing (e.g., preventing) the shape or the like of the first angle limiting plate 121 from being deformed by the heat.

The second angle limiting member 130 may include a second angle limiting plate 131 and a second support member 132.

The second angle limiting plate 131 may have a three-dimensional shape configured to have sides respectively extending in the first direction DR1, the second direction DR2, and the third direction DR3. For example, the second angle limiting plate 131 may have a rectangular parallelepiped plate shape. The second angle limiting plate 131 may be coupled to the second support member 132.

The second angle limiting plate 131 may extend in a direction in which the angle at which the deposition material is emitted from the nozzles 111 can be limited. The second angle limiting plate 131 may limit the emission area of the deposition material DM emitted in the radial form from the evaporation apparatus 100.

The second support member 132 may have a three-dimensional shape configured to have sides respectively extending in the first direction DR1, the second direction DR2, and the third direction DR3. For example, the second support member 132 may have a rectangular parallelepiped pillar shape.

The second support member 132 may function to entirely support the second angle limiting plate 131. For example, the shape of the second angle limiting plate 131 may be partially deformed by the heat radiated from the lower case 110. The second support member 132 may function to entirely support the second angle limiting plate 131, thereby reducing (e.g., preventing) the shape or the like of the second angle limiting plate 131 from being deformed by the heat.

The cooling fins 140 may include first cooling fins 141 and second cooling fins 142. The cooling fins 140 and the first and second heat exchangers 150 and 160 may be formed of a same material. For example, the cooling fins 140 and the first and second heat exchangers 150 and 160 may be formed of a material having a same thermal conductivity.

The first cooling fins 141 may include at least one of stainless steel, titanium, aluminum, and complex carbon.

The first cooling fins 141 may be coupled to the first angle limiting member 120. The first cooling fins 141 may have a three-dimensional shape configured to have sides respectively extending in the first direction DR1, the second direction DR2, and the third direction DR3. For example, the first cooling fins 141 may have a rectangular parallelepiped plate shape.

The second cooling fins 142 may be coupled to the second angle limiting member 130. The second cooling fins 142 may have a three-dimensional shape configured to have sides respectively extending in the first direction DR1, the second direction DR2, and the third direction DR3. For example, the second cooling fins 142 may have a rectangular parallelepiped plate shape.

In an embodiment of the disclosure, a process in which heat transfer may be made is as follows. First, the first and second angle limiting members 120 and 130 may receive heat transferred from the lower case 110. The heat transferred to the first and second angle limiting members 120 and 130 may be transferred to the cooling fins 140. The cooling fins 140 may have a wide surface area which the heat transferred from the first and second angle limiting members 120 and 130 can be radiated in the air, and cooling of the first and second angle limiting members 120 and 130 may be accelerated.

The density of the deposition material in accordance with an embodiment of the disclosure may be increased as temperature drops. Accordingly, the density of the deposition material piled up on surfaces of the first and second angle limiting members 120 and 130 may be increased as the temperature drops. Thus, a smaller volume of the deposition material can be piled up with respect to the same mass on the surfaces of the first and second angle limiting members 120 and 130, and covering of the nozzle 111 due to the deposition material can be reduced (e.g., prevented).

The evaporation apparatus 100 may include the first and second heat exchangers 150 and 160.

The first and second heat exchangers 150 and 160 may be spaced apart from each other in the first direction DR1 with the lower case 110 interposed between the first and second heat exchangers 150 and 160.

The first and second heat exchangers 150 and 160 may include a material having a high thermal conductivity. For example, the first and second heat exchangers 150 and 160 may include a metal (e.g., iron (Fe) or the like).

The first heat exchanger 150 may include a first heat exchanger body 151, first heat exchange fins 152, a first refrigerant material inlet 153, a first refrigerant material outlet 154, and the like.

The first heat exchanger body 151 may have a three-dimensional shape configured to have sides respectively extending in the first direction DR1, the second direction DR2, and the third direction DR3. For example, the first heat exchanger body 151 may have a rectangular parallelepiped shape configured with sides extending in the first direction DR1, the second direction DR2, and the third direction DR3.

The first heat exchange fins 152 may be coupled to the first heat exchanger body 151, and have a three-dimensional shape extending in the first to third directions DR1 to DR3. For example, the first heat exchange fins 152 may have a rectangular parallelepiped plate shape.

The first heat exchange fins 152 may overlap (e.g., overlap without being in direct contact) the first cooling fins 141 in a plan view. The first heat exchange fins 152 and the first cooling fins 141 may be alternately arranged.

The first refrigerant material inlet 153 and the first refrigerant material outlet 154 may be coupled to the first heat exchanger body 151, and have various shapes. For example, each of the first refrigerant material inlet 153 and the first refrigerant material outlet 154 may have a circular pillar shape, but the disclosure is not limited to the shape shown in FIG. 1.

A refrigerant material may be a liquid. For example, water (H₂O) may be used as the refrigerant material, but the disclosure is not limited thereto. The refrigerant material may be input to the inside of the first heat exchanger 150 through the first refrigerant material inlet 153. Also, the refrigerant material may be discharged to the outside of the first heat exchanger 150 through the first refrigerant material outlet 154.

Through the input and discharge of the refrigerant material, heat of the first heat exchanger 150 may be radiated to the outside of the first heat exchanger 150. As such a process is repeated, a temperature of the first heat exchanger 150 may be maintained equal (or substantially equal) to a temperature of the refrigerant material. For example, a temperature of the first heat exchange fins 152 coupled to the first heat exchanger 150 may also be maintained equal (or substantially equal) to the temperature of the refrigerant material.

The second heat exchanger 160 may include a second heat exchanger body 161, second heat exchange fins 162, a second refrigerant material inlet 163, a second refrigerant material outlet 164, and the like.

The second heat exchanger body 161 may have a three-dimensional shape configured to have sides respectively extending in the first direction DR1, the second direction DR2, and the third direction DR3. For example, the second heat exchanger body 161 may have a rectangular parallelepiped shape configured with sides extending in the first direction DR1, the second direction DR2, and the third direction DR3.

The second heat exchange fins 162 may be coupled to the second heat exchanger body 161, and have a three-dimensional shape extending in the first to third directions DR1 to DR3. For example, the second heat exchange fins 162 may have a rectangular parallelepiped plate shape.

In some embodiments, the second heat exchange fins 162 may overlap the second cooling fins 142 without being in direct contact with the second cooling fins 142 in a plan view. In some embodiments, the second heat exchange fins 162 and the second cooling fins 142 may be alternately arranged.

The second refrigerant material inlet 163 and the second refrigerant material outlet 164 may be coupled to the second heat exchanger body 161. The second refrigerant material inlet 163 and the second refrigerant material outlet 164 may have various shapes. For example, as shown in FIG. 1, each of the first refrigerant material inlet 153 and the first refrigerant material outlet 154 may have a circular pillar shape. However, the disclosure is not limited thereto.

A refrigerant material may be input to the inside of the second heat exchanger 160 through the second refrigerant material inlet 163. The input refrigerant material may be discharged to the outside of the second heat exchanger 160 through the second refrigerant material outlet 164.

Through the input and discharge of the refrigerant material, heat of the second heat exchanger 160 may be radiated to the outside of the second heat exchanger 160. As such a process is repeated, a temperature of the second heat exchanger 160 may be maintained equal (or substantially equal) to a temperature of the refrigerant material. For example, a temperature of the second heat exchange fins 162 coupled to the second heat exchanger 160 may also be maintained equal (or substantially equal) to the temperature of the refrigerant material.

In accordance with an embodiment of the disclosure, the first and second heat exchange fins 152 and 162 and the cooling fins 140 may be alternately arranged in the evaporation apparatus 100. Each of the cooling fins 140 may overlap the first and second heat exchange fins 152 and 162 having a large surface temperature difference with each of the cooling fins 140 in the third direction DR3. An amount of radiative heat radiated toward each of the first and second heat exchange fins 152 and 162 having a low surface temperature from each of the cooling fins 140 having a high surface temperature may be increased. Thus, the radiative heat of the first cooling fins 141 may be readily radiated in the air by the first heat exchange fins 152.

FIG. 2 is a schematic cross-sectional view taken along line I-I′ of the evaporation apparatus shown in FIG. 1.

Referring to FIGS. 1 and 2, in a cross-sectional view, the lower case 110, the first angle limiting member 120, the second angle limiting member 130, the first heat exchanger 150, and the second heat exchanger 160 are illustrated.

Hereinafter, descriptions of portions of the first and second angle limiting members 120 and 130 and the first and second heat exchangers 150 and 160, which overlap those described in FIG. 1, will be omitted.

The lower case 110 may include a nozzle 111, a crucible 112, a heating member 113, first and second inner plates 114 and 115, a first cover 116, a frame 117, and a heat insulating plate 118.

The lower case 110 may include an empty space for exposing the nozzle 111. In an embodiment, the lower case 110 may include an empty space having a shape extending in a direction (e.g., the second direction DR2) to expose (e.g., completely expose) multiple nozzles 111. In embodiments, the empty space of the lower case 110 may be covered with the heat insulating plate 118. In an area covered by the heat insulating plate 118, an area corresponding to the nozzle 111 may be opened such that an opening is located therein.

The crucible 112 may be configured to accommodate a deposition material DM therein. An internal space IS may be defined inside the crucible 112, and the deposition material DM may be accommodated in the internal space IS. The internal space IS may include a first internal space IS1, a second internal space IS2, and a third internal space IS3. The crucible 112 may be connected to the nozzle 111. The deposition material DM may be evaporated inside the crucible 112 to be emitted through the nozzle 111.

The heating member 113 may be located in a lateral direction (e.g., the first direction DR1) of the crucible 112. The heating member 113 may extend in a direction (e.g., the third direction DR3).

The heating member 113 may provide heat, and the heat provided by the heating member 113 may increase the temperature of the crucible 112. For example, the heat provided by the heating member 113 may increase the temperature of the internal space IS of the crucible 112.

The heating member 113 may evaporate the deposition material DM accommodated in the crucible 112, thereby forming a thin film on a target substrate.

The heating member 113 may include, for example, multiple heating plates. In embodiments, the heating member 113 may include a heating coil. In embodiments, the heating member 113 may not only extend in a direction (e.g., the third direction DR3) but also extend in another direction (e.g., the second direction DR2 as a direction perpendicular to the third direction DR3). In embodiments, the heating member 113 may have a form in which the heating member 113 is divided in the third direction DR3 perpendicular to the first direction DR1. In embodiments, the heating member 113 may be integrally formed along the third direction DR3.

The evaporation apparatus 100 may include a first inner plate 114 and ae second inner plate 115. The first inner plate 114 may divide the internal space IS into the first internal space IS1 and the second internal space IS2. The second inner plate 115 may divide the internal space IS into the second internal space IS2 and the third internal space IS3.

The deposition material DM may be accommodated in the first internal space IS1. Hereinafter, although an embodiment that the evaporation apparatus 100 includes the first inner plate 114 and the second inner plate 115 is described, the disclosure is not limited thereto. For example, functions of the first inner plate 114 and the second inner plate 115, which are described below, may be performed by one inner plate. Also, the evaporation apparatus 100 may include additional inner plates in addition to the first inner plate 114 and the second inner plate 115.

The first inner plate 114 may be disposed above the deposition material DM inside the crucible 112. The first inner plate 114 may include multiple penetration holes.

The first inner plate 114 may increase the internal pressure of the crucible 112 (or the atmospheric pressure of the first internal space IS1). The first inner plate 114 may improve deposition efficiency with which the deposition material DM heated and evaporated in the crucible 112 is deposited on the target substrate. The first inner plate 114 may prevent the deposition material in a mass unit from being discharged in the third direction DR3 of the crucible 112.

The second inner plate 115 may overlap the first inner plate 114 in the third direction DR3 inside the crucible 112. The second inner plate 115 may include multiple penetration holes.

The second inner plate 115 may lengthen a moving path through which the deposition material DM heated and evaporated in the crucible 112 is emitted. Accordingly, the deposition material DM may be effectively prevented from being deposited on the first cover 116, or the deposition material DM in the mass unit may be effectively prevented from be discharged.

In embodiments, a size of the penetration holes of the second inner plate 115 may be smaller than a size of the penetration holes of the first inner plate 114. Accordingly, a larger amount of the deposition material DM heated and evaporated in the crucible 112 may primarily pass through the penetration holes of the first inner plate 114.

The first cover 116 may be coupled to an upper side of the crucible 112. The first cover 116 and the crucible 112 may extend in a same direction (e.g., the first direction DR1).

The first cover 116 may have a plate type shape (e.g., a flat plate shape). The first cover 116 and the crucible 112 may be formed of, for example, a same material, but the disclosure is not limited thereto. FIG. 2 illustrates that the first cover 116 is separated from the crucible 112. However, the disclosure is not limited thereto, and in another embodiment, the first cover 116 and the crucible 112 may be integral with each other. In embodiments, the first cover 116 may be omitted.

The nozzle 111 may protrude in an upper direction (e.g., the third direction DR3) of the first cover 116. The nozzle 111 may have a plate shape including an opening through which the deposition material DM can be emitted.

The frame 117 may accommodate the crucible 112 and the heating member 113 therein. For example, the frame 117 may be formed in a box shape in which at least a portion of an upper side thereof is opened. The frame 117 may be coupled to the heat insulating plate 118. The frame 117 may protect components accommodated therein from the outside.

The frame 117 may include a heat insulating material. The frame 117 may prevent heat of the internal space IS from being leaked to the outside. A pipe (not shown) for providing a path through which the deposition material DM flows may be disposed inside the frame 117.

The heat insulating plate 118 may be disposed on the top of the first cover 116 and expose the nozzle 111. The heat insulating plate 118 may be coupled to the frame 117. The heat insulating plate 118 may prevent heat radiated from the heating member 113 and/or heat radiated from the crucible 112 from being leaked to the outside.

The heat insulating plate 118 may include an opening formed in the area corresponding to the nozzle 111. The width of opening of the heat insulating plate 118 may be gradually increased as approaching an area distant from the nozzle 111 from an area close to the nozzle 111. Accordingly, the deposition material DM emitted from the nozzle 111 may be radiated in a wider area while preventing heat generated at a lower portion of the heat insulating plate 118 (e.g., heat radiated from the heating member 113 and/or the crucible 112) from being radiated to an upper portion of the heat insulating plate 118.

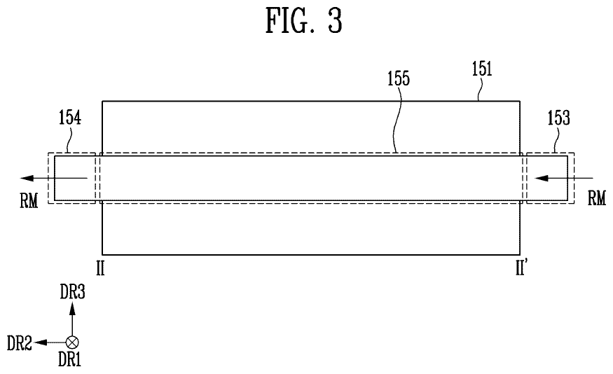

FIG. 3 is a schematic cross-sectional view taken along line II-II′ of the first heat exchange shown in FIG. 1.

Referring to FIGS. 1 and 3, the first heat exchanger 150 may include a first heat exchanger body 151, a first refrigerant material inlet 153, a first refrigerant material outlet 154, and a first refrigerant material moving path 155. Hereinafter, descriptions of portions of the first heat exchanger body 151, the first refrigerant material inlet 153, and the first refrigerant material outlet 154, which overlap those described in FIG. 1, will be omitted.

The first refrigerant material moving path 155 may extend from the first refrigerant material inlet 153, and be located inside the first heat exchanger body 151. The shape of the first refrigerant material moving path 155 is not limited to the shape shown in FIG. 3. For example, the first refrigerant material moving path 155 may have various shapes including a curved shape and the like.

A refrigerant material RM may be input to the inside of the first heat exchanger 150 through the first refrigerant material inlet 153. The input refrigerant material RM may receive heat transferred from the first heat exchanger body 151 surrounding the first refrigerant material moving path 155 while moving through the first refrigerant material moving path 155. The temperature of the refrigerant material RM may be increased as the refrigerant material RM receives the heat transferred from the first heat exchanger body 151. The refrigerant material RM of which temperature is increased may be discharged to the outside (e.g., in the air) through the first refrigerant material outlet 154. As such a process is repeated, the refrigerant material may discharge heat inside the first heat exchanger 150 to the outside of the first heat exchanger 150.

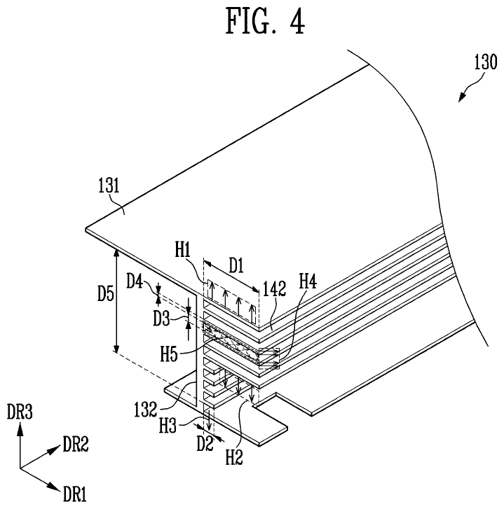

FIG. 4 is a perspective view illustrating the second angle limiting member shown in FIG. 1.

Portions described with reference to FIG. 4 may be equally applied to the first angle limiting member 120 shown in FIG. 1.

Referring to FIGS. 1 and 4, the second angle limiting member 130 may include a second angle limiting plate 131, a second support member 132, and second cooling fins 142.

At least one of the second cooling fins 142 may extend by a first length D1 in the first direction DR1 from the second support member 132. At least another one of the second cooling fins 142 may extend by a second length D2 in the first direction DR1 from the second support member 132. In embodiments, the first length D1 and the second length D2 may be different from each other. For example, the first length D1 may be greater than the second length D2. In embodiments, the first length D1 and the second D2 may be the same (or substantially same).

Two cooling fines adjacent to each other among the second cooling fins 142 may be spaced apart from each other. For example, two cooling fins adjacent to each other in the third direction DR3 among the second cooling fins 142 may be spaced apart from each other by a third length D3 in the third direction DR3.

The second cooling fins 142 may have a thickness (e.g., a predetermined thickness). For example, a thickness of at least one of the second cooling fins 142 in the third direction DR3 may be a fourth length D4.

A cooling fine disposed at an uppermost end among the second cooling fins 142 may be spaced apart from a cooling fine disposed at a lowermost end among the second cooling fins 142 by a fifth length D5.

In FIG. 4, it is illustrated that the number of second cooling fins 142 is 10. However, the number of second cooling fins 142 is not limited thereto. For example, the number of second cooling fins 142 may be less than or greater than 10.

The second cooling fins 142 may radiate heat. According to positions at which the heat is radiated, the head radiated from the second cooling fins 142 may be divided into first heat H1, second heat H2, third heat H3, fourth heat H4, fifth heat H5, and the like.

The first heat H1 may correspond to heat radiated in a direction (e.g., the third direction DR3) through an upper surface of the second cooling fin disposed at the uppermost end among the second cooling fins 142.

A second cooling fin disposed at a lowermost end among second cooling fins 142 extending by the first length D1 in the first direction DR1 from the second support member 132 may include a surface not overlapping a cooling fin adjacent to the second cooling fin in the third direction DR3, and radiate the second heat H2 in the opposite direction of the third direction DR3 through the surface.

The third heat H3 may correspond to heat radiated in the opposite direction of the third direction DR3 through a lower surface of the second cooling fin disposed at the lowermost end among the second cooling fins 142.

The fourth heat H4 may correspond to heat radiated in the first direction DR1 from side surfaces of the second cooling fins 142.

The fifth heat H5 may correspond to heat radiated between two adjacent cooling fins among the second cooling fins 142.

The heat radiated through the second cooling fins 142 may have the following relationship with the number of second cooling fins 142. As the number of second cooling fins 142 increases, the surface area with which the second angle limiting member 130 can radiate heat in the air may increase, and therefore, a larger amount of the first to third heats H1 to H3 may be radiated in the air.

The heat radiated through the second cooling fins 142 may have the following relationship with the length of the second cooling fins 142. As the length of the second cooling fins 142 in the first direction DR1 increases, the surface area with which the second angle limiting member 130 can radiate heat in the air may increase, and therefore, a larger amount of the first to fourth heats H1 to H4 may be radiated in the air.

On the other hand, the fifth heat H5 among the heats radiated through the second cooling fins 142 may have the following relationship with the number of second cooling fins 142. In case that the fifth length D5 is constant, as the number of second cooling fins 142 increases, the distance between the second cooling fins 142 may decrease. In other words, a distance between adjacent second cooling fins 142 in the third direction DR3 may decrease. Each of the second cooling fins 142 may radiate a smaller amount of radiative heat as second cooling fins 142 having a smaller surface temperature difference are disposed at a closer distance.

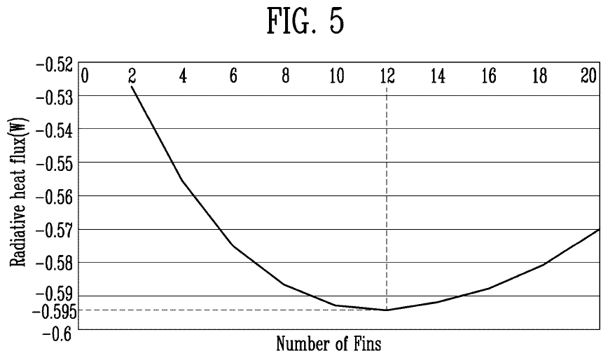

FIG. 5 is a graph illustrating radiative heat radiated according to a number of second cooling fins of the second angle limiting member shown in FIG. 4.

Referring to FIGS. 4 and 5, the horizontal axis shown in FIG. 5 may correspond to the number of second cooling fins 142 coupled to the second angle limiting member 130. The vertical axis shown in FIG. 5 represents flux of radiative heat (e.g., the first heat H1, the second heat H2, the third heat H3, the fourth heat H4, and the fifth heat H5) radiated in the air from the second angle limiting member 130.

In case that the number of second cooling fins 142 increases, the surface area with which the second angle limiting member 130 can radiate heat in the air may increase. As the surface area of the second angle limiting member 130 increases, the flux of the radiative heat radiated in the air from the second angle limiting member 130 may gradually increase. For example, in the graph shown in FIG. 5, the flux of the radiative heat radiated in the air from the second angle limiting member 130 may gradually increase as the number of second cooling fins 142 increases until the number of the second cooling fins 142 becomes 12. In case that the number of the second cooling fins 142 is 12, radiative heat of 0.595 W (Watt) may be radiated, which corresponds to a maximum value among radiative heats radiated in the air from the second angle limiting member 130.

On the other hand, as the number of second cooling fins 142 increases, the distance between the second cooling fins 142 may be decreased. In other words, the distance between second cooling fins 142 adjacent to each other in the third direction DR3 may be decreased. Each of the second cooling fins 142 may radiate a smaller amount of radiative heat in the air as second cooling fins 142 having a smaller surface temperature difference are disposed at a closer distance. For example, in the graph shown in FIG. 5, as the number of second cooling fins 142 increases greater than 12, the flux of radiative heat radiated in the air from the second angle limiting member 130 may gradually decrease.

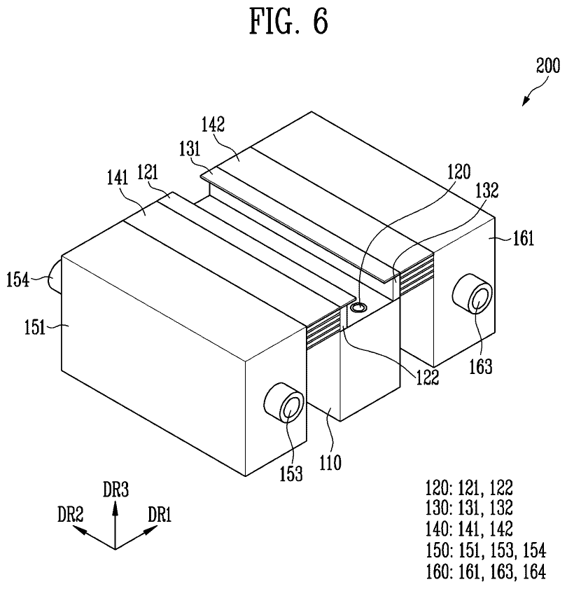

FIG. 6 is a perspective view illustrating an evaporation apparatus in accordance with another embodiment of the disclosure.

Referring to FIG. 6, as compared with FIG. 1, the evaporation apparatus 200 may not include the first heat exchange fins 152 and the second heat exchange fins 162. The first cooling fins 141 may be coupled to (e.g., directly coupled to) a side surface of the first heat exchanger 150, and the second cooling fins 142 may be coupled to (e.g., directly coupled to) a side surface of the second heat exchanger 160.

Temperatures of the first angle limiting member 120 and the second angle limiting member 130 may rise as the first angle limiting member 120 and the second angle limiting member 130 receive heat radiated from the lower case 110. The first angle limiting member 120 may transfer (e.g., directly transfer), to the first heat exchanger 150, heat received from the lower case 110 through the first cooling fins 141. The second angle limiting member 130 may transfer (e.g., directly transfer), to the second heat exchanger 160, heat received from the lower case 110 through the second cooling fins 142.

A refrigerant material input to the first refrigerant material inlet 153 may be discharged to the outside of the first heat exchanger 150 through the first refrigerant material outlet 154 in a state in which the temperature of the first heat exchanger 150 is increased due to the heat received from the lower case 110. As such a process is repeated, the heat which the first angle limiting member 120 receives from the lower case 110 may be radiated in the air.

Similarly, a refrigerant material input to the second refrigerant material inlet 163 may be discharged to the outside of the second heat exchanger 160 through the second refrigerant material outlet 164 in a state in which the temperature of the second heat exchanger 160 is increased due to the heat received from the lower case 110. As such a process is repeated, the heat which the second angle limiting member 130 receives from the lower case 110 may be radiated in the air.

In accordance with the disclosure, there can be provided an evaporation apparatus in which the emission angle limit of a deposition material is not changed.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. An evaporation apparatus comprising:
a lower case that accommodates a deposition material;
a nozzle mounted on the lower case and emitting the deposition material;
a first angle limiting member including a first support member and a first angle limiting plate connected to the first support member and extending, from the first support member, in a direction that limits an angle of the deposition material emitted from the nozzle;
a second angle limiting member including a second support member and a second angle limiting plate connected to the second support member and extending, from the second support member, in a direction that limits the angle of the deposition material emitted from the nozzle;
a plurality of first cooling fins connected to a side surface of the first angle limiting member; and
a first heat exchanger having a plurality of first heat exchange fins, each of the plurality of the first heat exchange fins located between adjacent ones of the plurality of first cooling fins.

2. The evaporation apparatus of claim 1, wherein
the first angle limiting member overlaps the lower case in a direction, and
the plurality of first cooling fins extend from the first angle limiting member not to overlap the lower case in the direction.

3. The evaporation apparatus of claim 2, wherein the plurality of first heat exchange fins overlap the plurality of first cooling fins in the direction without being in direct contact with the plurality of first cooling fins.

4. The evaporation apparatus of claim 1, wherein the plurality of first cooling fins and the plurality of first heat exchange fins are alternately arranged in the direction.

5. The evaporation apparatus of claim 1, wherein
each of the first angle limiting plate and the second angle limiting plate extends in a first direction and a second direction intersecting the first direction,
each of the first support member and the second support member is fixed to the lower case, extends in a third direction intersecting the first and second directions, and supports corresponding one of the first angle limiting plate and the second angle limiting plate, and
the first angle limiting member and the second angle limiting member are spaced apart from each other in the first direction.

6. The evaporation apparatus of claim 5, wherein a length of one of the plurality of first cooling fins and a length of another one of the plurality of first cooling fins are different in the first direction.

7. The evaporation apparatus of claim 1, wherein the first angle limiting member and the second angle limiting member include at least one of stainless steel, titanium, aluminum, and complex carbon.

8. The evaporation apparatus of claim 1, wherein the first heat exchanger includes:
a refrigerant material inlet for inputting a refrigerant material;
a refrigerant material moving path connected to the refrigerant material inlet, the refrigerant material moving path being located inside the first heat exchanger, the refrigerant material moving path transferring the refrigerant material; and
a refrigerant material outlet connected to an outside of the first heat exchanger, the refrigerant material outlet discharging, to outside, the refrigerant material transferred through the refrigerant material moving path.

9. The evaporation apparatus of claim 1, further comprising:
a plurality of second cooling fins connected to a side surface of the second angle limiting member; and
a second heat exchanger having a plurality of second heat exchange fins, each of the plurality of second heat exchange fins located between adjacent ones of the plurality of second cooling fins.

10. The evaporation apparatus of claim 9, wherein
the second angle limiting member overlaps the lower case in a direction, and
the plurality of second cooling fins extend from the second angle limiting member not to overlap the lower case in the direction.

11. The evaporation apparatus of claim 9, wherein the plurality of second heat exchange fins overlap the plurality of second cooling fins in the direction without being in direct contact with the plurality of second cooling fins.

12. An evaporation apparatus comprising:
a lower case that accommodates a deposition material;
a nozzle mounted on the lower case, and emitting the deposition material;
a first angle limiting member including a first support member and a first angle limiting plate connected to the first support member and extending, from the first support member, in a direction that limits an angle of the deposition material emitted from the nozzle;
a second angle limiting member including a second support member and a second angle limiting plate connected to the second support member and extending, from the second support member, in a direction that limits the angle of the deposition material emitted from the nozzle;
a plurality of first cooling fins connected to a side surface of the first angle limiting member; and
a first heat exchanger in contact with at least one of the plurality of first cooling fins.

13. The evaporation apparatus of claim 12, wherein
the first angle limiting member overlaps the lower case in a direction, and
the plurality of first cooling fins extend from the first angle limiting member not to overlap the lower case in the direction.

14. The evaporation apparatus of claim 12, wherein
each of the first angle limiting plate and the second angle limiting plate extends in a first direction and a second direction intersecting the first direction,
each of the first support member and the second support member is fixed to the lower case, extends in a third direction intersecting the first and second directions, and supports corresponding one of the first angle limiting plate and the second angle limiting plate, and
the first angle limiting member and the second angle limiting member are spaced apart from each other in the first direction.

15. The evaporation apparatus of claim 14, wherein a length of one of the plurality of first cooling fins and a length of another one of the plurality of first cooling fins are different in the first direction.

16. The evaporation apparatus of claim 12, wherein the first angle limiting member and the second angle limiting member include at least one of stainless steel, titanium, aluminum, and complex carbon.

17. The evaporation apparatus of claim 12, wherein the first heat exchanger includes:
a refrigerant material inlet for inputting a refrigerant material;
a refrigerant material moving path connected to the refrigerant material inlet, the refrigerant material moving path being located inside the first heat exchanger, the refrigerant material moving path transferring the refrigerant material; and
a refrigerant material outlet connected to an outside of the first heat exchanger, the refrigerant material outlet discharging, to outside, the refrigerant material transferred through the refrigerant material moving path.

18. The evaporation apparatus of claim 12, further comprising:
a plurality of second cooling fins connected to a side surface of the second angle limiting member; and
a second heat exchanger in contact with at least one of the plurality of second cooling fins.

19. The evaporation apparatus of claim 18, wherein
the second angle limiting member overlaps the lower case in a direction, and
the plurality of second cooling fins extend from the second angle limiting member not to overlap the lower case in the direction.
